(19) United States
(12) Patent Application Publication
(10) Pub. No.: US 2024/0068888 A1
(43) Pub. Date: Feb. 29, 2024

(54) DETECTION DEVICE

(71) Applicant: TDK CORPORATION, Tokyo (JP)

(72) Inventor: Takashi KATO, Tokyo (JP)

(73) Assignee: TDK CORPORATION, Tokyo (JP)

(21) Appl. No.: 18/350,087

(22) Filed: Jul. 11, 2023

(30) Foreign Application Priority Data
Aug. 24, 2022 (JP) 2022-133471

(51) Int. Cl. G01L 1/16; G01L 1/14

(52) U.S. Cl. CPC G01L 1/16; G01L 1/14

(57) ABSTRACT

A detection device includes a base plate, a piezoelectric element disposed on the base plate with an insulating member therebetween and generating a pressing force corresponding to an electromotive force, an electrostatic capacitance sensor detecting an electrostatic capacitance of the base plate, a wiring member (first wiring member) electrically connected to the piezoelectric element, and a wiring member (second wiring member) electrically connected to the electrostatic capacitance sensor.

### CROSS-REFERENCE TO RELATED APPLICATIONS

This application is based upon and claims the benefit of priority from Japanese Patent Application No. 2022-133471, filed on Aug. 24, 2022. The entire contents of which are incorporated herein by reference.

### TECHNICAL FIELD

The present disclosure relates to a detection device.

### BACKGROUND

Regarding a detection device in the related art, for example, there is an electronic instrument disclosed in PCT International Publication No. WO2017/122466. This electronic instrument includes an operation unit receiving an input from an operator, a contact detection unit detecting contact with respect to the operation unit, a piezoelectric element detecting change in a pressing load with respect to the operation unit, and a control unit executing first processing when the piezoelectric element detects change in a first pressing load. The control unit executes second processing when the piezoelectric element detects change in a second pressing load and when the contact detection unit continuously detects contact until the second pressing load is detected after the first pressing load is detected.

### SUMMARY

The detection device described above utilizes a so-called piezoelectric effect phenomenon in which an electromotive force is generated in accordance with distortion caused by a pressing force applied to a piezoelectric element. For the sake of expansion of usage, such detection devices are required to have a constitution capable of performing multi-detection including an electromotive force from a piezoelectric element.

The present disclosure has been made in order to resolve the foregoing problems, and an object thereof is to provide a detection device capable of performing multi-detection including an electromotive force from a piezoelectric element.

A detection device according to an aspect of the present disclosure includes a base plate, a piezoelectric element disposed on the base plate with an insulating member therebetween and generating an electromotive force corresponding to a pressing force, an electrostatic capacitance sensor detecting an electrostatic capacitance of the base plate, a first wiring member electrically connected to the piezoelectric element, and a second wiring member electrically connected to the electrostatic capacitance sensor.

In this detection device, an electromotive force generated in the piezoelectric element due to a pressing force can be extracted via the first wiring member, and an electrostatic capacitance of the base plate can be extracted via the second wiring member separately from an electromotive force of the piezoelectric element. Therefore, in this detection device, multi-detection based on an electromotive force from the piezoelectric element and an electrostatic capacitance of the base plate can be performed.

The base plate may have a first surface having the piezoelectric element disposed thereon and a second surface positioned on a side opposite to the first surface and serving as an attachment surface of the detection device with respect to an attachment object. Both the first wiring member and the second wiring member may be positioned on the first surface side of the base plate. The second wiring member may be closer to the first surface of the base plate than the first wiring member. An attachment area between the base plate and the attachment object can be sufficiently secured by providing the attachment surface in the base plate with respect to the attachment object. Therefore, detection of an electrostatic capacitance of the base plate can be favorably performed.

The second wiring member may be separate from the first wiring member. In this case, an influence of detection of an electrostatic capacitance via the second wiring member on detection of an electromotive force of the piezoelectric element via the first wiring member can be curbed.

The second wiring member may be integrated with the first wiring member. In this case, simplification of a constitution of the detection device can be achieved.

The detection device may further include a determination unit configured to perform determination of tapping and releasing on the basis of the electromotive force or the electrostatic capacitance. In this case, determination of tapping and determination of releasing can be accurately performed regardless of a way of applying a pressing force.

### BRIEF DESCRIPTION OF THE DRAWINGS

FIG. 1 is a schematic view illustrating a detection device according to an embodiment of the present disclosure.

FIG. 2 is a perspective view illustrating a constitution of the detection device illustrated in FIG. 1.

FIG. 3 is a view illustrating an example of an electromotive force generated in a piezoelectric element with respect to tapping and releasing.

FIG. 4 is a view illustrating a typical example of an electromotive force generated in the piezoelectric element when a long-press input is made.

FIG. 5 is a chart diagram showing a phase of determination of tapping and determination of releasing.

FIG. 6 is a flowchart showing operation of the detection device illustrated in FIG. 1.

FIG. 7 is a schematic view illustrating the detection device according to a modification example.

### DETAILED DESCRIPTION

Hereinafter, with reference to the drawings, a preferred embodiment of a detection device according to an aspect of the present disclosure will be described in detail.

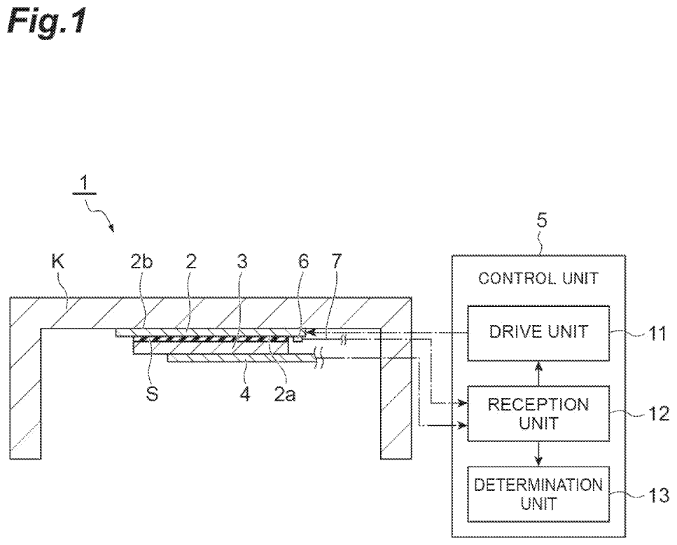

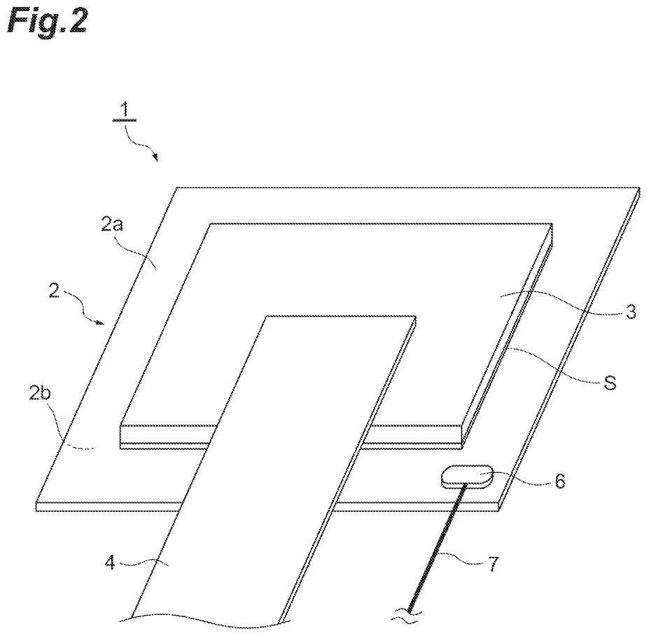

FIG. 1 is a schematic view illustrating a detection device according to an embodiment of the present disclosure. FIG. 2 is a perspective view illustrating a constitution of the detection device illustrated in FIG. 1. As illustrated in FIGS. 1 and 2, a detection device 1 is constituted to include a base plate 2, a piezoelectric element 3 disposed on one surface side of the base plate 2, a wiring member (first wiring member) 4 electrically connected to the piezoelectric element 3, and a control unit 5 controlling operation of the detection device 1. In the detection device 1, for example, an electromotive force from the piezoelectric element 3 can be obtained on the basis of stress applied to the base plate 2 (distortion of the base plate 2) due to contact or the like of a finger or the like. An electromotive force from the piezoelectric element 3 is output to the control unit 5 via the wiring member 4.

In addition, the detection device 1 includes an electrostatic capacitance sensor 6 disposed on one surface side of the base plate 2. The electrostatic capacitance sensor 6 is a sensor for detecting an electrostatic capacitance of the base plate 2. The electrostatic capacitance sensor 6 may be a self-capacitance sensor or a mutual capacitance sensor. The electrostatic capacitance sensor 6 operates on the basis of a drive signal output from the control unit 5 and outputs a signal indicating a detection result to the control unit 5.

In the example of FIG. 1, the detection device 1 is attached to a rear surface of a casing K of an external device (not illustrated). The casing K is made of a resin, for example. A double-sided tape, an adhesive, or the like can be used, for example, for joining the detection device 1 and the casing K to each other. When the detection device 1 and the casing K are joined to each other, the entire surface of the base plate 2 may be joined to the rear surface of the casing K. In addition, in a state where a recessed portion is provided on the rear surface of the casing K and the recessed portion is closed with the base plate 2, a circumferential edge portion of the base plate 2 may be joined to an opening edge portion of the recessed portion. In a state of being joined to the casing K, the base plate 2 may not necessarily be flat and may be in a curved state.

The base plate 2 is formed to have a rectangular shape using a conductive metal material, for example. The base plate 2 has a square planar shape, for example. The base plate 2 may be constituted as a diaphragm. Examples of a constituent material of the base plate 2 include a Ni—Fe alloy, Ni, brass, and stainless steel. The base plate 2 has a main surface (first surface) 2a and a main surface 2b (second surface) making a pair facing sides opposite to each other. The main surface 2a is a surface having the piezoelectric element 3 disposed thereon. The main surface 2b is a surface serving as an attachment surface of the detection device 1 with respect to an attachment object. That is, the main surface 2b is a surface joined to the rear surface of the casing K.

The piezoelectric element 3 includes a piezoelectric element body and a pair of external electrodes. The piezoelectric element body has a rectangular parallelepiped shape which is flat in a thickness direction. The rectangular parallelepiped shape also includes a shape in which corner portions and ridge line portions are chamfered and a shape in which corner portions and ridge line portions are rounded. The piezoelectric element 3 is joined to the main surface 2a of the base plate 2, for example, in a state where the center of the piezoelectric element body and the center of the base plate 2 coincide with each other. A double-sided tape, an adhesive, or the like can be used, for example, for joining the piezoelectric element 3 and the base plate 2 to each other. In the present embodiment, in consideration of an electrostatic capacitance of the base plate 2 detected by the electrostatic capacitance sensor 6, an insulating member S is used for joining the piezoelectric element 3 and the base plate 2 to each other. For example, an electric insulation adhesive can be used as the insulating member S.

The piezoelectric element body has a pair of main surfaces. One main surface is a surface facing the base plate 2 side. The other main surface is a surface facing a side opposite to the base plate 2. The pair of main surfaces have shapes which are the same as each other in a plan view of the piezoelectric element 3. Here, the pair of main surfaces has a square shape of which a length of one side is smaller than that of the base plate 2, for example. A thickness of the piezoelectric element body is larger than a thickness of the base plate 2, for example. In a plan view of the piezoelectric element 3, the center of the piezoelectric element body coincides with the center of the base plate 2. In addition, in a plan view of the piezoelectric element 3, each side of the piezoelectric element body is individually parallel to each side of the base plate 2.

The piezoelectric element body has no internal electrode and is constituted of a single piezoelectric layer. The piezoelectric layer is constituted using a piezoelectric material. In the present embodiment, the piezoelectric layer is constituted using a piezoelectric ceramic material. Examples of the piezoelectric ceramic material include PZT[Pb(Zr,Ti)O₃], PT(PbTiO₃), PLZT[(Pb,La)(Zr,Ti)O₃], and barium titanate. The piezoelectric layer is constituted of a sintered body of a ceramic green sheet including the piezoelectric ceramic material described above, for example.

The pair of external electrodes have a rectangular parallelepiped shape which is flat in the thickness direction. The rectangular parallelepiped shape also includes a shape in which corner portions and ridge line portions are chamfered and a shape in which corner portions and ridge line portions are rounded. Thicknesses of the pair of external electrodes are approximately the same as each other, and both are sufficiently smaller than the thickness of the piezoelectric element body. The external electrodes are constituted using a conductive material. Examples of a conductive material include Ag, Pd, and a Ag—Pd alloy. The external electrodes are constituted of sintered bodies of conductive pastes including the conductive material described above, for example.

The wiring member 4 is constituted of a flexible printed circuit (FPC), for example. The wiring member 4 has a structure in which a conductor is covered with a covering member. The conductor is formed of a highly conductive material such as copper, for example. A covering member is formed of a non-conductive resin such as a polyimide resin, for example. One end of the wiring member 4 is positioned on a surface of the piezoelectric element 3 on a side opposite to the base plate 2 and is electrically connected to the external electrodes of the piezoelectric element 3. The other end of the wiring member 4 is drawn out in an in-plane direction of the base plate 2 and is electrically connected to the control unit 5 that is an output destination of an electromotive force generated in the piezoelectric element 3.

As illustrated in FIGS. 1 and 2, the electrostatic capacitance sensor 6 described above is provided in a region on the main surface 2a of the base plate 2 exposed from the piezoelectric element 3. Disposition of the electrostatic capacitance sensor 6 in the region is not particularly limited. In the present embodiment, the electrostatic capacitance sensor 6 is disposed at one of two corner portions positioned in a drawing direction of the wiring member 4 from the piezoelectric element 3. The electrostatic capacitance sensor 6 has a wiring member 7. The wiring member 7 is a signal line through which a drive signal from the control unit 5 and a signal indicating a detection result from the electrostatic capacitance sensor 6 are exchanged. One end of the wiring member 7 is electrically connected to the electrostatic capacitance sensor 6 on one surface side of the base plate 2. The other end of the wiring member 7 is drawn out from the electrostatic capacitance sensor 6 in the same direction as the wiring member 4 and is electrically connected to the control unit 5.

In the present embodiment, the wiring member 7 of the electrostatic capacitance sensor 6 is drawn out in the in-plane direction of the base plate 2 from the electrostatic capacitance sensor 6 disposed on one surface side of the base plate 2, and the wiring member 4 of the piezoelectric element 3 is drawn out in the in-plane direction of the base plate 2 from a surface of the piezoelectric element 3 on a side opposite to the base plate 2. Therefore, as illustrated in FIG. 1, both the wiring member 4 and the wiring member 7 are positioned on the main surface 2a side of the base plate 2. Further, in a state where the detection device 1 is attached to the casing K, the wiring member 7 of the electrostatic capacitance sensor 6 is in a state of being closer to the main surface 2a of the base plate 2 than the wiring member 4 of the piezoelectric element 3. Accordingly, the wiring member 7 of the electrostatic capacitance sensor 6 is in a state of being closer to the attachment object (here, the casing K) of the detection device 1 than the wiring member 4 of the piezoelectric element 3.

In the detection device 1 having the constitution described above, multi-detection can be performed based on an electromotive force from the piezoelectric element 3 and an electrostatic capacitance of the base plate 2. Hereinafter, an application example of multi-detection by the detection device 1 will be described.

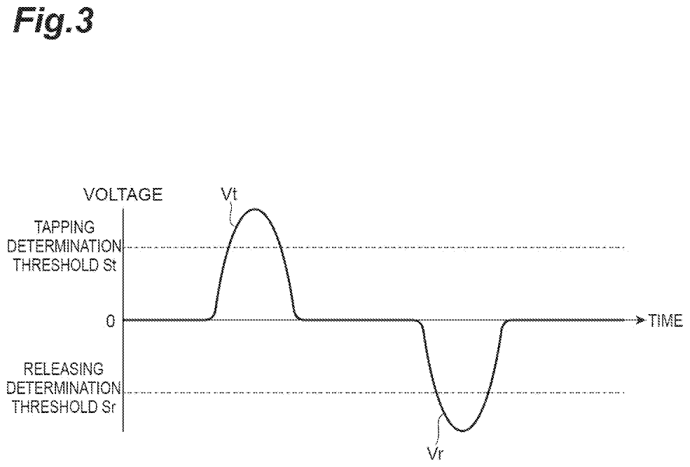

FIG. 3 is a view illustrating an example of an electromotive force generated in a piezoelectric element with respect to tapping and releasing. As illustrated in the same diagram, if tapping and releasing are performed by an operator using a finger or the like with respect to a front surface of the casing K, an electromotive force corresponding to a pressing force is generated in the piezoelectric element 3. Typically, the piezoelectric element 3 generates a positive tapping voltage Vt corresponding to tapping and then generates a negative release voltage Vr corresponding to releasing. The tapping voltage Vt and the release voltage Vr have a sinusoidal waveform with respect to a time axis, for example.

With respect to such an electromotive force from the piezoelectric element 3, in a technique in the related art, as illustrated in FIG. 2, a tapping determination threshold St used for determination of tapping and a releasing determination threshold Sr used for determination of releasing are set in advance. The tapping determination threshold St may be set to have a value larger than that of the releasing determination threshold Sr. Determination of tapping (determination of contact of a finger or the like with the casing K) is performed at a timing when the tapping voltage Vt exceeds the tapping determination threshold St, and thereafter, determination of releasing (determination of separation of a finger or the like from the casing K) is performed at a timing when the release voltage Vr exceeds the releasing determination threshold Sr.

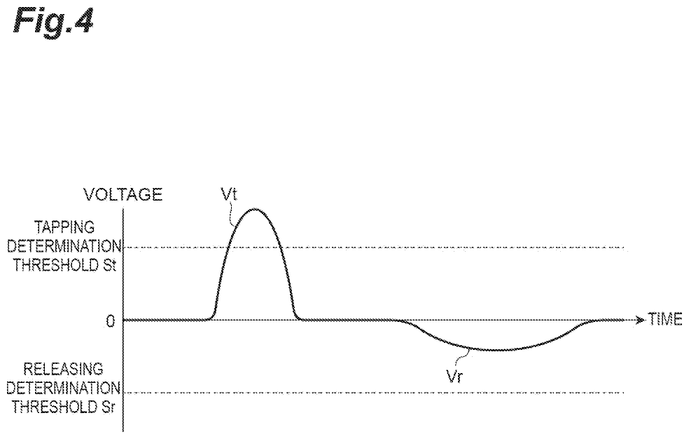

On the other hand, a form of a pressing force applied to the piezoelectric element 3 varies depending on a way of tapping and releasing. For example, when a long press is performed with a finger, for example, as illustrated in FIG. 4, the piezoelectric element 3 generates a week release voltage Vr corresponding to a week pressing force for a relatively long period of time. In this case, it is conceivable that the release voltage Vr do not exceed the releasing determination threshold Sr and determination of releasing not be correctly performed even though a finger or the like is actually separated from the casing K. If the releasing determination threshold Sr is simply set to have a small value on an assumption of a long press, it is conceivable that the release voltage Vr be judged to exceed the releasing determination threshold Sr due to noise or the like and accuracy of determination of releasing deteriorate.

In consideration of the foregoing problems, instead of setting the releasing determination threshold Sr with respect to a voltage value of the release voltage Vr, the control unit 5 is constituted to be able to accurately perform determination of releasing regardless of a way of applying a pressing force using the electrostatic capacitance sensor 6 described above in combination with the piezoelectric element 3. Hereinafter, a constitution of the control unit 5 will be described in detail.

The control unit 5 is physically constituted of a computer system including memories such as a RAM and a ROM, a processor (arithmetic circuit) such as a CPU, a communication interface, and a storage unit such as a hard disk. The control unit 5 functions by causing the CPU of the computer system to execute a program stored in the memory. The control unit 5 may be constituted of a micro-controller, an integrated circuit, or the like. In the present embodiment, the control unit 5 is constituted of a micro-controller.

As illustrated in FIG. 1, the control unit 5 includes a drive unit 11, a reception unit 12, and a determination unit 13. The drive unit 11 is a part for controlling driving of the electrostatic capacitance sensor 6. The drive unit 11 inputs a drive signal used for driving of the electrostatic capacitance sensor 6 to the electrostatic capacitance sensor 6. For example, triangular waves can be used as a drive signal. In the present embodiment, if the casing K is tapped with a finger or the like, since an electrostatic capacitance of the base plate 2 increases and a charging/discharging time is lengthened, counting of triangular waves decreases. On the contrary, if a finger or the like is released from the casing K, since an electrostatic capacitance of the base plate 2 decreases and the charging/discharging time is shortened, counting of triangular waves increases. Therefore, in the electrostatic capacitance sensor 6, an electrostatic capacitance of the base plate 2 can be detected on the basis of fluctuation in counting of triangular waves, and ON determination corresponding to tapping and OFF determination corresponding to releasing can be performed on the basis of the detected electrostatic capacitance.

The reception unit 12 is a part for receiving an electromotive force from the piezoelectric element 3 and an electrostatic capacitance from the electrostatic capacitance sensor 6. The reception unit 12 receives an electromotive force from the piezoelectric element 3 via the wiring member 4 of the piezoelectric element 3 and receives an electrostatic capacitance from the electrostatic capacitance sensor 6 via the wiring member 7 of the electrostatic capacitance sensor 6. In the present embodiment, the reception unit 12 outputs an electromotive force from the piezoelectric element 3 to the drive unit 11 and the determination unit 13 and outputs an electrostatic capacitance from the electrostatic capacitance sensor 6 to the determination unit 13.

The determination unit 13 is a part for performing determination of tapping and determination of releasing. Specifically, the determination unit 13 performs determination of tapping on the basis of at least one of comparison between the voltage value of the tapping voltage Vt and the tapping determination threshold St and ON determination of the electrostatic capacitance sensor 6 and performs determination of releasing on the basis of OFF determination of the electrostatic capacitance sensor 6. In the present embodiment, the determination unit 13 performs determination of tapping on the basis of comparison between the voltage value of the tapping voltage Vt and the tapping determination threshold St and performs determination of releasing on the basis of OFF determination of the electrostatic capacitance sensor 6. In addition, the determination unit 13 determines an intensity of tapping on the basis of a peak voltage value Vtp of the tapping voltage Vt. The determination unit 13 individually generates information indicating results of determination of tapping, determination of an intensity of tapping, and determination of releasing and outputs it to an external device. In the external device, processing based on each piece of received information is executed.

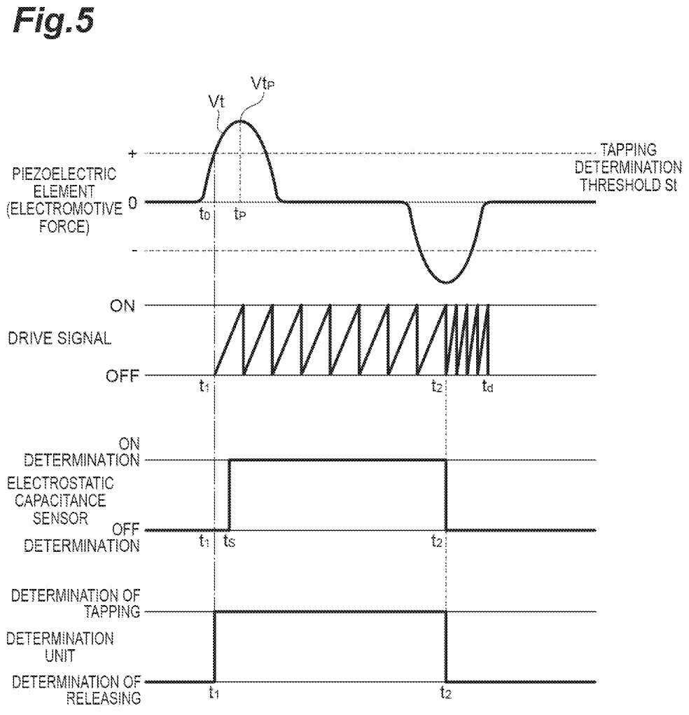

FIG. 5 is a chart diagram showing a phase of determination of tapping and determination of releasing. As illustrated in FIG. 5, if the casing K is tapped with a finger or the like at a time t0, the positive tapping voltage Vt corresponding to tapping is generated in the piezoelectric element 3. The determination unit 13 performs determination of tapping on the basis of a fact that the voltage value of the tapping voltage Vt has exceeded the tapping determination threshold St at a time t1 after the time t0. The determination unit 13 acquires the peak voltage value Vtp of the tapping voltage Vt after determination of tapping. The determination unit 13 determines the intensity of tapping on the basis of the acquired peak voltage value Vtp of the tapping voltage Vt. For example, the peak voltage value Vtp can be acquired by comparing a current value of the tapping voltage Vt and a preceding detection value. Specifically, when the current value of the tapping voltage Vt falls below the preceding detection value, the preceding detection value can be taken as the peak voltage value Vtp.

The electrostatic capacitance sensor 6 starts operation within a period from the time t1 when the voltage value of the tapping voltage Vt reaches the tapping determination threshold St to a time tp when it reaches the peak. In the example of FIG. 5, the electrostatic capacitance sensor 6 starts operation at the time t1 when the voltage value of the tapping voltage Vt reaches the tapping determination threshold St. That is, at the time t1, a drive signal is input from the drive unit 11 to the electrostatic capacitance sensor 6, and the electrostatic capacitance sensor 6 starts to detect an electrostatic capacitance of the base plate 2. Since the casing K is tapped at a point of time when the electrostatic capacitance sensor 6 starts to detect an electrostatic capacitance of the base plate 2, the electrostatic capacitance sensor 6 performs ON determination at a time is immediately after the time t1.

If a finger or the like is released from the casing K, the negative release voltage Vr corresponding to releasing is generated in the piezoelectric element 3. However, in the present embodiment, the release voltage Vr is not used for determination of releasing. If a finger or the like is released from the casing K, counting of triangular waves increases at a time t2 after releasing. On the basis of this, the electrostatic capacitance sensor 6 performs OFF determination at the time t2. The determination unit 13 performs determination of releasing at the time t2 on the basis of OFF determination of the electrostatic capacitance sensor 6.

The electrostatic capacitance sensor 6 stops operation at a time td after a predetermined period has elapsed from OFF determination. For example, a period from the time t2 to the time td is arbitrarily set within a range not affecting next detection. For example, the electrostatic capacitance sensor 6 stops in a next arithmetic cycle after OFF determination.

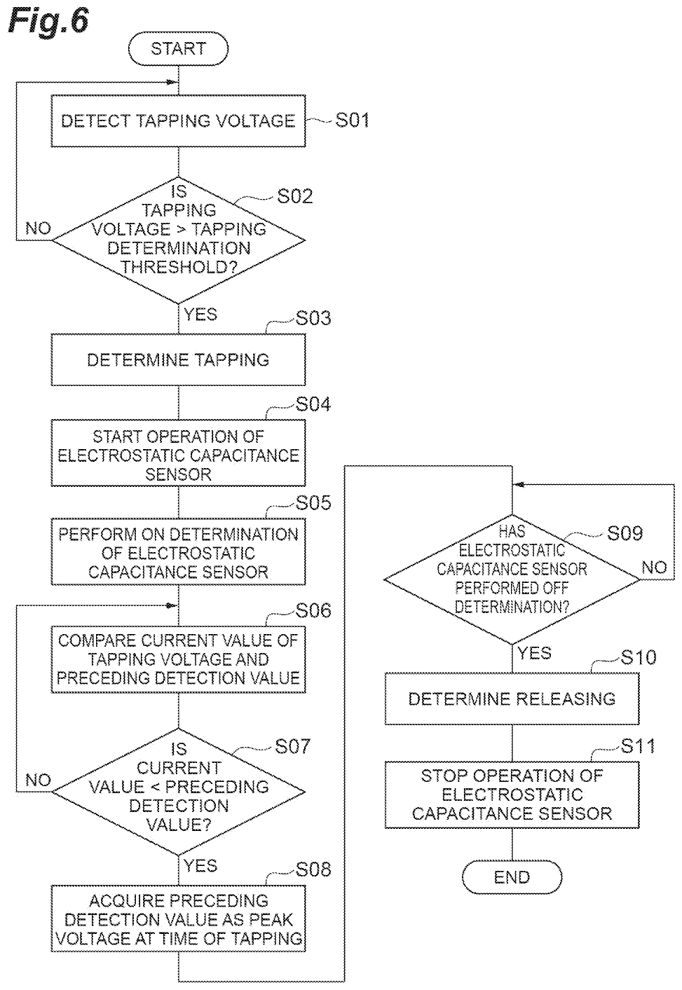

FIG. 6 is a flowchart showing operation of the detection device illustrated in FIG. 1. As illustrated in FIG. 6, in the detection device 1, first, the tapping voltage Vt is detected (Step S01). Next, it is judged whether or not the tapping voltage Vt has exceeded the tapping determination threshold St (Step S02). When it is judged in Step S02 that the tapping voltage Vt has not exceeded the tapping determination threshold St, the process returns to Step S01 and detection of the tapping voltage Vt continues. When it is judged in Step S02 that the tapping voltage Vt has exceeded the tapping determination threshold St, determination of tapping is performed (Step S03). After determination of tapping, operation of the electrostatic capacitance sensor 6 is started (Step S04), and ON determination of the electrostatic capacitance sensor 6 is performed (Step S05).

After ON determination of the electrostatic capacitance sensor 6, the current value of the tapping voltage Vt and the preceding detection value are compared to each other (Step S06), and it is judged whether or not the current value of the tapping voltage Vt has fallen below the preceding detection value (Step S07). When it is judged in Step S07 that the current value of the tapping voltage Vt is equal to or larger than the preceding detection value, it is assumed that the tapping voltage Vt has not attained the peak and the processing of Step S06 and Step S07 is repeatedly executed. When it is judged in Step S06 that the current value of the tapping voltage Vt has fallen below the preceding detection value, it is assumed that the tapping voltage Vt has attained the peak and the preceding detection value is acquired as the peak voltage value Vtp at the time of tapping (Step S08).

After the peak voltage value Vtp is acquired, it is judged whether or not OFF determination of the electrostatic capacitance sensor 6 has been performed (Step S09). When it is judged in Step S09 that OFF determination of the electrostatic capacitance sensor 6 has not been performed, Step S09 is repeatedly executed. When it is judged in Step S10 that OFF determination of the electrostatic capacitance sensor 6 has been performed, determination of releasing is performed (Step S10). After a predetermined period has elapsed from determination of releasing, that is, after a predetermined period has elapsed from OFF determination, operation of the electrostatic capacitance sensor 6 is stopped (Step S11), and the processing ends.

As described above, in the detection device 1, an electromotive force generated in the piezoelectric element 3 due to a pressing force can be extracted via the wiring member (first wiring member) 4, and an electrostatic capacitance of the base plate 2 can be extracted via the wiring member (second wiring member) 7 separately from an electromotive force of the piezoelectric element 3. Therefore, in the detection device 1, multi-detection based on an electromotive force from the piezoelectric element 3 and an electrostatic capacitance of the base plate 2 can be performed.

In the present embodiment, the base plate 2 has the main surface (first surface) 2a having the piezoelectric element 3 disposed thereon and the main surface (second surface) 2b positioned on a side opposite to the main surface 2a and serving as an attachment surface of the detection device 1 with respect to the casing K (attachment object). Further, both the wiring member 4 and the wiring member 7 may be positioned on the main surface 2a side of the base plate 2. The wiring member 7 may be closer to the main surface 2a of the base plate 2 than the wiring member 4. An attachment area between the base plate 2 and the attachment object can be sufficiently secured by providing the attachment surface in the base plate 2 with respect to the attachment object. Therefore, detection of an electrostatic capacitance of the base plate 2 can be favorably performed.

In the present embodiment, the wiring member 7 of the electrostatic capacitance sensor 6 is separate from the wiring member 4 of the piezoelectric element 3. Accordingly, an influence of detection of an electrostatic capacitance via the wiring member 7 on detection of an electromotive force of the piezoelectric element 3 via the wiring member 4 can be curbed.

In the present embodiment, the detection device 1 further includes the determination unit 13 performing determination of tapping and releasing on the basis of an electromotive force or an electrostatic capacitance. Accordingly, determination of tapping and determination of releasing can be accurately performed regardless of a way of applying a pressing force.

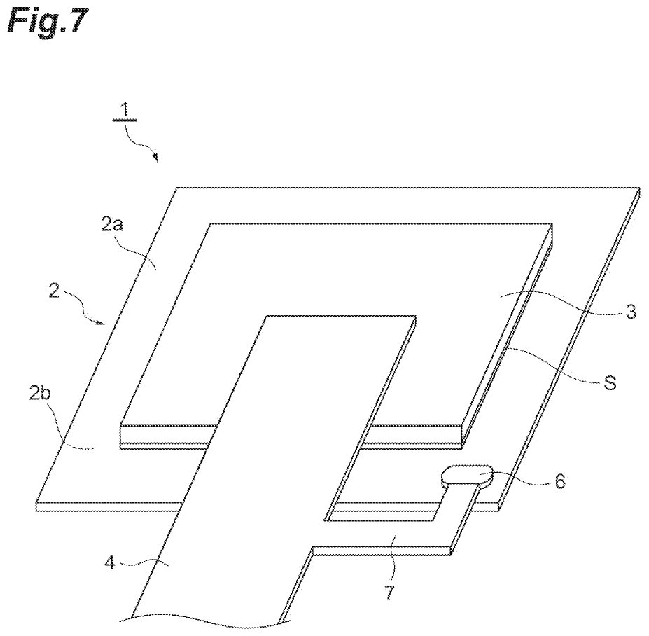

The present disclosure is not limited to the foregoing embodiment. In the foregoing embodiment, the wiring member 4 of the piezoelectric element 3 and the wiring member 7 of the electrostatic capacitance sensor 6 are separate from each other, but the wiring member 7 of the electrostatic capacitance sensor 6 and the wiring member 4 of the piezoelectric element 3 may be integrated with each other. That is, the wiring member 4 of the piezoelectric element 3 may also serve as the wiring member 7 of the electrostatic capacitance sensor 6. In this case, for example, as illustrated in FIG. 7, one end side of the wiring member 4 (FPC) may be caused to branch such that one branch is electrically connected to the piezoelectric element 3 and the other branch is electrically connected to the electrostatic capacitance sensor 6.

In the foregoing embodiment, determination of tapping is performed on the basis of comparison between the voltage value of the tapping voltage Vt and the tapping determination threshold St, but determination of tapping may be performed on the basis of ON determination of the electrostatic capacitance sensor 6. In this case, the determination unit 13 may perform determination of tapping at the time ts when ON determination of the electrostatic capacitance sensor 6 is performed instead of the time t1 when the voltage value of the tapping voltage Vt reaches the tapping determination threshold St.

In the foregoing embodiment, the electrostatic capacitance sensor 6 starts operation at the time t1 when the voltage value of the tapping voltage Vt reaches the tapping determination threshold St, but operation of the electrostatic capacitance sensor 6 may start at an arbitrary time within a period from the time t1 when the voltage value of the tapping voltage Vt reaches the tapping determination threshold St to the time ts when it reaches the peak. Operation of the electrostatic capacitance sensor 6 may start at the time ts when the voltage value of the tapping voltage Vt reaches the peak.

What is claimed is:

1. A detection device comprising:
a base plate;
a piezoelectric element disposed on the base plate with an insulating member therebetween and generating an electromotive force corresponding to a pressing force;
an electrostatic capacitance sensor detecting an electrostatic capacitance of the base plate;
a first wiring member electrically connected to the piezoelectric element; and
a second wiring member electrically connected to the electrostatic capacitance sensor.

2. The detection device according to claim 1,
wherein the base plate has a first surface having the piezoelectric element disposed thereon and a second surface positioned on a side opposite to the first surface and serving as an attachment surface of the detection device with respect to an attachment object,
wherein both the first wiring member and the second wiring member are positioned on the first surface side of the base plate, and
wherein the second wiring member is closer to the first surface of the base plate than the first wiring member.

3. The detection device according to claim 1,
wherein the second wiring member is separate from the first wiring member.

4. The detection device according to claim 1,
wherein the second wiring member is integrated with the first wiring member.

5. The detection device according to claim 1 further comprising:
a determination unit configured to perform determination of tapping and releasing on the basis of the electromotive force or the electrostatic capacitance.
